(19) United States
(12) Patent Application Publication
(10) Pub. No.: US 2021/0028407 A1
(43) Pub. Date: Jan. 28, 2021

(54) DISPLAY DEVICE AND PRODUCTION METHOD THEREFOR

(71) Applicant: SHARP KABUSHIKI KAISHA, Sakai City, Osaka (JP)

(72) Inventors: AKIRA SAKAI, Sakai City, Osaka (JP); MASAHIRO HASEGAWA, Sakai City, Osaka (JP)

(21) Appl. No.: 17/042,893

(22) PCT Filed: Mar. 29, 2018
(86) PCT No.: PCT/JP2018/013290

§ 371 Date: Sep. 28, 2020

(51) Int. Cl. H01L 51/52; H01L 33/48; G06F 3/041

(52) U.S. Cl. CPC H01L 51/5281; G06F 2203/04103; G06F 3/041; H01L 33/48

(57) ABSTRACT

A display device including a light-emitting layer, a touch panel, a phase difference layer, and a linear polarizing layer, wherein the touch panel and the phase difference layer are provided between the light-emitting layer and the linear polarizing layer, the touch panel includes a touch panel base material and a touch panel electrode, the touch panel base material is formed from a resin film, a phase difference of the resin film is (λ₀/4)+α₀ at reference wavelength λ₀, the phase difference layer is formed from a polymerizable liquid crystal material, a phase difference α of the phase difference layer is α₀ at reference wavelength λ₀, and a slow axis of the resin film is orthogonal to a slow axis of the phase difference layer.

### TECHNICAL FIELD

The disclosure relates to a display device, and particularly to a display device having an antireflective layer and a touch panel layer.

### BACKGROUND ART

A touch panel function or an antireflective function may be added to a display device as additional functions.

For example, PTL 1 described below discloses a display provided with a touch panel with reduced reflection and excellent viewability. PTL 2 described below discloses adding an antireflective function to a touch panel sensor.

### CITATION LIST

### Patent Literature

PTL 1: JP 2009-226932 A (Publication date: Oct. 8, 2009)

PTL 2: JP 2013-242692 A (Publication date: Dec. 5, 2013)

### SUMMARY

### Technical Problem

An object of the disclosure is to obtain good display characteristics while reducing the thickness of the display device.

### Solution to Problem

A display device according to an aspect of the disclosure is a display device including: a light-emitting layer; a touch panel; a phase difference layer; and a linear polarizing layer, wherein the touch panel and the phase difference layer are provided between the light-emitting layer and the linear polarizing layer, the touch panel includes a touch panel base material and a touch panel electrode, the touch panel base material is formed from a resin film, a phase difference of the resin film is (λ₀/4)+α₀ at reference wavelength λ₀, the phase difference layer is formed from a polymerizable liquid crystal material, a phase difference α of the phase difference layer is α₀ at reference wavelength λ₀, and a slow axis of the resin film is orthogonal to a slow axis of the phase difference layer.

### Advantageous Effects of Disclosure

According to an aspect of the disclosure, good display characteristics can be obtained while reducing the thickness of the display device.

### BRIEF DESCRIPTION OF DRAWINGS

FIG. 1 is a diagram illustrating a cross-sectional configuration of a display device according to the disclosure.

FIG. 2 is a diagram illustrating a cross-sectional configuration of a display device according to a known example.

FIG. 3 is a diagram illustrating a cross-sectional configuration of a display device according to a known example.

FIG. 4 is a diagram schematically illustrating a manufacturing flow for the display device according to the disclosure.

FIG. 5 is a diagram illustrating a typical example of a phase difference wavelength dispersion.

FIG. 6 is a diagram illustrating a phase difference wavelength dispersion for the display device according to the disclosure.

FIG. 7 is a diagram illustrating viewing angle characteristics of circular polarizers according to the disclosure and a known example.

FIG. 8 is a diagram illustrating layer configurations of the circular polarizers illustrated in FIG. 7 with the viewing angle characteristics.

### DESCRIPTION OF EMBODIMENTS

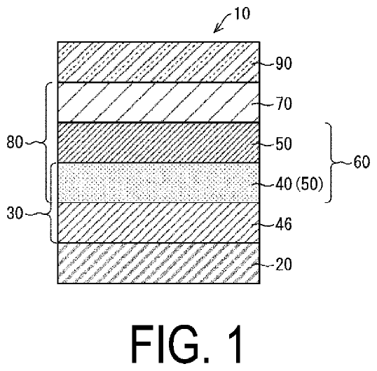

FIG. 1 is a diagram illustrating a cross-sectional configuration of a display device 10 according to the disclosure. A touch panel function and an antireflective function are added to the display device 10 as additional functions.

### Overall Configuration

As illustrated in FIG. 1, the display device 10 includes a touch panel 30 that has a touch panel function, and a circular polarizer 80 that has an antireflective function, layered on a light-emitting layer 20. A cover glass 90, which serves as a protective member, is disposed on the upper layer of the circular polarizer 80. Hereinafter, the constituent elements will be described sequentially.

### Light-Emitting Layer

The light-emitting layer 20 may be, for example, an Organic Electro Luminescence (EL) display (Organic Light Emitting Diode (OLED)) element, but is not limited thereto, and may be an inorganic light-emitting diode display element or a quantum dot light emitting diode display element.

### Touch Panel

The touch panel 30 includes a touch panel base material 40 and a touch panel electrode 46 provided on the touch panel base material 40.

The touch panel base material 40 is formed from a high reliability resin film, which is also referred to as a COP film, for example. Examples of the high reliability resin include cycloolefin polymers, but are not limited thereto.

The touch panel electrode 46 is formed in a desired form (transparent conductive film) on the touch panel base material 40 with a transparent conductive material such as Indium Tin Oxide (ITO), for example.

Note that the touch panel 30 of the configuration example illustrated in FIG. 1 is an out cell type, and the touch panel 30 is provided outside the light-emitting layer 20, separate from the light-emitting layer 20.

### Circular Polarizer

The circular polarizer 80 includes a linear polarizing layer 70 that linearly polarizes light, and a phase difference layer 50 that imparts a phase difference to the light.

In the configuration example illustrated in FIG. 1, the circular polarizer 80 includes the touch panel base material 40. In other words, the display device 10 uses the touch panel base material 40 as a part of a layer that imparts a phase difference to light in the circular polarizer 80.

In the configuration example illustrated in FIG. 1, the touch panel base material 40 functions as a base material in the touch panel 30, and functions as a layer having a phase difference in the circular polarizer 80.

### Total Phase Difference

In order to suppress the reflection of light by using circular polarization, a layer having a phase difference of λ/4 needs to be interposed between the linear polarizing layer and the reflective surface on which incident light reflects. Here, the sum of the phase difference between the linear polarizing layer and the reflective surface is defined as the total phase difference.

In the display device 10, the phase difference combining the phase difference of the touch panel base material 40 and the phase difference of the phase difference layer 50 is the total phase difference 60.

### Wavelength Dispersion of Phase Difference

The antireflective function is required not only to suppress reflection at a specific wavelength, but also to suppress reflection across the visible light range. This is because, in a case that the reflectivity varies depending on the wavelength, the reflected light is colored and the display quality is reduced.

In order to suppress the reflectivity across the visible light range, the total phase difference is preferably increased in proportion to the wavelength.

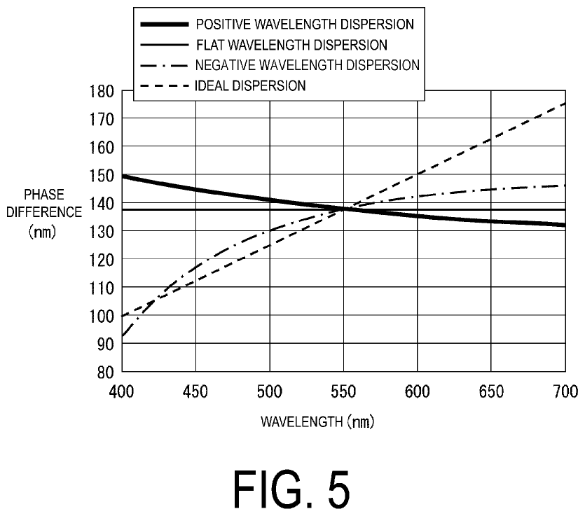

This will be described with reference to FIG. 5. FIG. 5 is a diagram illustrating a typical example of a phase difference wavelength dispersion.

The dashed line in FIG. 5 indicates ideal dispersion. The ideal dispersion is a wavelength dispersion in which the absolute value of the phase difference increases in proportion to the wavelength. This ideal dispersion is an ideal wavelength dispersion from the perspective of suppressing the coloration of the reflected light.

The bold line in FIG. 5 indicates a positive wavelength dispersion. The positive wavelength dispersion is a wavelength dispersion in which the absolute value of the phase difference decreases as the wavelength gets longer.

The solid line in FIG. 5 indicates a flat wavelength dispersion. The flat wavelength dispersion is a wavelength dispersion in which the absolute value of the phase difference is constant regardless of the wavelength. Note that a flat phase difference indicates a material designed for achieving a flat phase difference, and does not strictly imply that the phase difference is constant.

Both the positive wavelength dispersion and the flat wavelength dispersion are non-preferable wavelength dispersions from the perspective of suppressing the coloration of the reflected light.

The dot-dash line in FIG. 5 indicates a negative wavelength dispersion. The negative wavelength dispersion is a wavelength dispersion in which the absolute value of the phase difference increases as the wavelength gets longer. From the perspective of suppressing the coloration of the reflected light, it is preferable to achieve the negative wavelength dispersion as illustrated in FIG. 5, even if the ideal dispersion is not achieved.

Note that, in any of the wavelength dispersions illustrated in FIG. 5, λ₀/4 is achieved, with the reference wavelength λ₀ at 550 nm.

### Design of Phase Difference

The design of the phase difference will be described below. In the configuration example illustrated in FIG. 1, the total phase difference is a sum of the phase difference of the touch panel base material 40 and the phase difference of the phase difference layer 50. In the configuration example illustrated in FIG. 1, the touch panel base material 40 is formed from a cycloolefin polymer as described above. The cycloolefin polymer has a flat wavelength dispersion. Then, the phase difference of the touch panel base material 40 is set to (λ₀/4)+α₀ substantially constant with respect to wavelength (where α₀ denotes a constant value for each wavelength).

On the other hand, the phase difference layer 50 is formed from a polymerizable liquid crystal material. A material with a positive wavelength dispersion is used for the polymerizable liquid crystal material. Then, the phase difference of the phase difference layer 50 is α, and has a value of α₀ in a case of the reference wavelength λ₀. Note that a specific value of α is, for example, 50 nm to 200 nm.

Here, the orientation direction of the polymerizable liquid crystal material is the direction in which the slow axis is orthogonal to the slow axis of the touch panel base material 40. By the two slow axes being orthogonal, the total phase difference will be the difference between the phase difference of the touch panel base material 40 and the phase difference of the phase difference layer 50, specifically, ((λ₀/4)+α₀)−α=(λ₀/4)+α₀−α(λ₀/4 in a case of the reference wavelength λ₀). Thereby, the phase difference between the touch panel base material and the phase difference layer, in other words, the total phase difference, is a characteristic of the negative wavelength dispersion λ/4. The wavelength dispersion of the total phase difference is the negative wavelength dispersion because the positive wavelength dispersion (phase difference layer 50) is subtracted from the flat wavelength dispersion (touch panel base material 40). This causes the total phase difference to be the negative wavelength dispersion close to the ideal dispersion.

### Illustration of Total Phase Difference

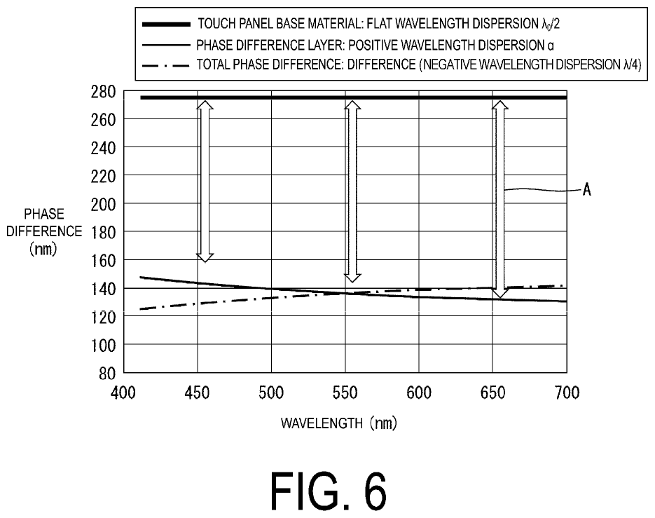

The sum of the phase differences will be described based on FIG. 6. FIG. 6 is a diagram illustrating a phase difference wavelength dispersion for the display device according to the disclosure. Note that in FIG. 6, an example of α₀=λ₀/4 is illustrated.

The bold line in FIG. 6 indicates the wavelength dispersion of the touch panel base material 40. Because the touch panel base material 40 is formed from a material having a flat wavelength dispersion, the phase difference of the touch panel base material 40 is substantially constant regardless of the wavelength. The value of the phase difference is (λ₀/4)+α₀=(λ₀/4)+(λ₀/4)=λ₀/2.

The solid line in FIG. 6 indicates the wavelength dispersion of the phase difference layer 50. Because the phase difference layer 50 is formed from a material having a positive wavelength dispersion, the phase difference of the phase difference layer 50 decreases as the wavelength increases. The value of the phase difference has a characteristic of a positive wavelength dispersion with the phase difference α (α₀=λ₀/4 at the reference wavelength). In other words, a λ/4 plate (λ₀/4 at the reference wavelength λ₀) formed from a positive wavelength dispersion material can be used for the phase difference layer 50. In this case, compared to a case that a λ/4 plate constituted of other materials such as a negative wavelength dispersion material is used, it is preferable that the phase difference layer 50 can be configured at a lower cost.

Here, in the configuration example illustrated in FIG. 1, the slow axis of the touch panel base material 40 and the slow axis of the phase difference layer 50 are orthogonal to each other. Therefore, the total phase difference between the touch panel base material 40 and the phase difference layer 50 is a difference between the phase difference of the touch panel base material 40 and the phase difference of the phase difference layer 50. In FIG. 6, the total phase difference is indicated by the dot-dash line.

The value of the total phase difference has a characteristic of a negative wavelength dispersion λ/4 where (λ₀/4)+α₀−α=λ₀/4+((λ₀/4)−α) (where α is λ₀/4 at the reference wavelength λ₀). In other words, the wavelength dispersion of the total phase difference is a negative wavelength dispersion because the positive wavelength dispersion is subtracted from the flat wavelength dispersion.

As described above, in the display device 10 illustrated in FIG. 1, a phase difference of λ/4 of a negative wavelength dispersion is realized in the circular polarizer 80.

### Manufacturing Flow

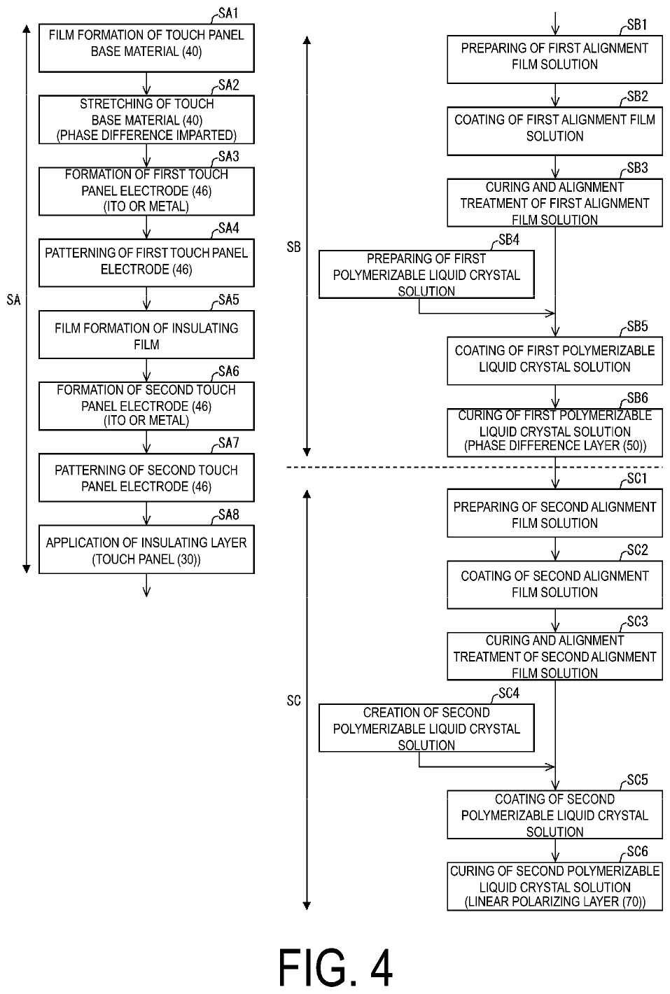

A manufacturing flow of a layered body of the touch panel 30, the phase difference layer 50, and the linear polarizing layer 70 will be described based on FIG. 4. FIG. 4 is a diagram schematically illustrating a manufacturing flow for the display device according to the disclosure.

In the configuration example illustrated in FIG. 4, the touch panel 30 has a configuration in which two layers of touch panel electrodes 46 (first and second touch panel electrodes) are formed on the touch panel base material 40 with an insulating layer interposed therebetween.

Both the phase difference layer 50 and the linear polarizing layer 70 are formed by application of a polymerizable liquid crystal material. Alignment films subjected to alignment treatment are formed as respective underlayers for orientation imparting to the applied polymerizable liquid crystal material. Hereinafter, the process will be described sequentially.

### Formation of Touch Panel (SA)

Steps SA1 to SA8 illustrate manufacturing steps of the touch panel 30.

Step SA1: a touch panel base material 40 is prepared. Specifically, a cycloolefin polymer is film-formed as a touch panel base material 40.

Step SA2: a phase difference is imparted to the touch panel base material 40. Specifically, the film-formed cycloolefin polymer is stretched to impart a phase difference. In this case, the phase difference is λ/2.

Steps SA3 to SA8: a touch panel electrode 46 formed from ITO or metal is formed on the touch panel base material 40. Because the touch panel base material 40 is formed from a cycloolefin polymer having heat resistance, it is possible to form the touch panel electrode 46 without damaging the touch panel base material 40 or the like.

As described above, the touch panel electrode 46 has a dual-layer structure. Thus, the formation of the touch panel electrode 46 is performed in the order of forming a first touch panel electrode (step SA3), patterning the first touch panel electrode (step SA4), film-forming an insulating film on the first touch panel electrode (step SA5), forming a second touch panel electrode (step SA6), patterning the second touch panel electrode (step SA7), and coating and film-forming an insulating film on the second touch panel electrode (step SA8). Thus, the touch panel 30 is formed.

### Formation of Phase Difference Layer (SB)

Steps SB1 to SB6 illustrate manufacturing steps of the phase difference layer 50. As described above, the phase difference layer has a configuration in which the polymerizable liquid crystal layer is layered on the alignment film subjected to alignment treatment.

Step SB1: a first alignment film solution is created. The first alignment film imparts orientation to the polymerizable liquid crystal layer as an underlayer of the polymerizable liquid crystal layer.

Step SB2: the first alignment film solution is coated. Specifically, the first alignment film solution created in step SB1 is coated on the side of the touch panel base material 40 on which the touch panel electrode 46 is not formed.

Step SB3: curing and alignment treatment of the first alignment film solution is performed. The curing is performed by heat curing or UV irradiation, and the alignment treatment is performed by rubbing or light irradiation, or the like.

Here, the orientation direction of the first alignment film is the direction in which the slow axis of the phase difference layer 50 formed thereon and the slow axis of the touch panel base material 40 are orthogonal to each other.

Step SB4: a solution of a first polymerizable liquid crystal for forming the phase difference layer 50 is created. Here, a relatively inexpensive material with a positive wavelength dispersion is used rather than an expensive material with a negative wavelength dispersion.

Step SB5: a first polymerizable liquid crystal solution is coated. Specifically, the first polymerizable solution created in step SB4 is coated on the first alignment film that has been subjected to the alignment treatment in step SB3.

Step SB6: curing of the first polymerizable liquid crystal solution is performed. The curing is performed by heat curing or UV irradiation, or the like. Examples of curing conditions include prebaking at 120° C., irradiating with UV light to polymerize, and then performing main baking at 230° C.

Because the cured first polymerizable liquid crystal layer is formed on the first alignment film having orientation, the cured first polymerizable liquid crystal layer has orientation. Here, the phase difference is λ/4. In this way, the phase difference layer 50 is formed.

### Formation of Linear Polarizing Layer (SC)

Steps SC1 to SC6 illustrate manufacturing steps of the linear polarizing layer 70. As described above, the linear polarizing layer 70 has a configuration in which the polymerizable liquid crystal layer is layered on the alignment film subjected to alignment treatment. This configuration is the same as the phase difference layer 50 described above. Therefore, the manufacturing step of the linear polarizing layer 70 is similar to the manufacturing step of the phase difference layer 50. In other words, steps SC1 to SC6 are the same as those in which the first alignment film in steps SB1 to SB6 is replaced with a second alignment film and the first polymerizable liquid crystal is replaced with a second polymerizable liquid crystal.

Hereinafter, differences from steps SB1 to SB6 in steps SC1 to SC6 will be described.

In the formation of the phase difference layer 50, a layer having the phase difference of λ/4 is formed by using a material having a positive wavelength dispersion as the first polymerizable liquid crystal. More specifically, a liquid crystal material having a positive double refraction (for example, rod-shaped liquid crystal) or a liquid crystal material having a negative double refraction (for example, a discotic liquid crystal) is used for the first polymerizable liquid crystal used in the phase difference layer 50. However, a case that a liquid crystal material having a negative double refraction is used as the first polymerizable liquid crystal is preferable than a case that a liquid crystal material having a positive double refraction is used, in that the viewing angle characteristics of the display device 10 can be improved.

In contrast, in the formation of the linear polarizing layer 70, a material that absorbs vibration components in a specific direction of light is used as the second polymerizable liquid crystal. More specifically, a material in which a dichroic pigment is mixed with a polymerizable liquid crystal can be used as the second polymerizable liquid crystal. In this case, in a case that the polymerizable liquid crystal is used as the host, the dichroic pigment is mixed thereto as a guest, and the host liquid crystal is oriented by the alignment film, the dichroic pigment, which is the guest, is oriented in the same manner.

Although the orientation direction of the second polymerizable liquid crystal serving as the optical axis of the linear polarizing layer 70 is described as a direction in which the angle formed with the delay axis of the phase difference layer 50 is 45 degrees, the orientation direction is not limited thereto. The orientation direction of the second polymerizable liquid crystal is preferably such that the orientation direction is parallel to the side of the frame of the display device or the angle formed with the side of the frame of the display device is 45 degrees.

In a case that the orientation direction of the second polymerizable liquid crystal is parallel to the side of the frame of the display device, the alignment treatment is facilitated and a display device having excellent viewing angle characteristics can be easily configured.

On the other hand, in a case that the orientation direction of the second polymerizable liquid crystal is set so that the angle formed with the side of the frame of the display device is 45 degrees, the orientation direction of the second polymerizable liquid crystal is more likely to appropriate for polarized sunglasses worn on a viewer of the display device. Polarized sunglasses often have its absorption axis in a horizontal direction or a vertical direction in a case of being worn. Therefore, in the case that the angle described above is 45 degrees, the emission light from the display device is less completely blocked by the polarized sunglasses.

The display device 10 is obtained by layering the layered body formed as described above on the light-emitting layer 20 and layering the cover glass 90 to the outermost layer.

Note that the above is a description of one example of the display device 10, and other configurations and the like are possible.

For example, in the description above, a configuration is described in which the light-emitting layer 20, the touch panel 30, the phase difference layer 50, and the linear polarizing layer 70 are layered in the order, but the order of layering is not limited to this. For example, the order of the touch panel 30 and the phase difference layer 50 may be reversed, and the display device 10 may be layered in the order of the light-emitting layer 20, the phase difference layer 50, the touch panel 30, and the linear polarizing layer 70. Specifically, to the layered body of the touch panel 30 and the phase difference layer 50, by forming the linear polarizing layer 70 on the surface side of the touch panel 30 of the layered body and forming the light-emitting layer 20 on the surface side of the phase difference layer 50 of the layered body, the display device 10 may be obtained in which the light-emitting layer 20, the phase difference layer 50, the touch panel 30, and the linear polarizing layer 70 described above are layered in the order.

### Other Manufacturing Methods

Note that the method of manufacturing the display device 10 is not limited to the above.

For example, the touch panel 30, the phase difference layer 50, and the linear polarizing layer 70 may be individually created and layered to each other via an adhesive layer or a bonding layer.

The method of manufacturing the phase difference layer 50 is not limited to the method of manufacturing in which the polymerizable liquid crystal material is applied to the touch panel base material 40, but may be a manufacturing method in which the polymerizable liquid crystal material is applied to the linear polarizing layer 70.

The material that forms the phase difference layer 50 is not limited to a material having a positive wavelength dispersion, but a material having a flat wavelength dispersion or a negative wavelength dispersion can be used. However, as described above, a case that a material having a positive wavelength dispersion is used is preferable that the cost of the phase difference layer 50, and thus the display device 10, can be reduced.

The method of manufacturing the linear polarizing layer 70 is not limited to the method of manufacturing in which the polymerizable liquid crystal material is applied to the phase difference layer 50, but may be a method of manufacturing in which the polymerizable liquid crystal material is applied to a base material such as the cover glass 90.

The method of manufacturing the linear polarizing layer 70 is not limited to the method of manufacturing by application, but a method using a linear polarizer formed from a separately created film may also be used.

The outermost layer of the display device 10 is not limited to the cover glass 90, but can be a variety of layers, such as a plastic film.

Note that examples of the cycloolefin polymer for forming the touch panel base material 40 include, but are not limited to, ZeonorFilm (trade name) formed by ZEON Corporation, Arton Film (trade name) formed by JSR, and the like.

The polymerizable liquid crystal material for forming the phase difference layer 50 uses a material having a positive wavelength dispersion, but it is also possible to use a material with a negative wavelength dispersion.

### Known Layer Configuration 1

Layer configurations of display devices 10 and 100 or the like will be described below while compared to a known example.

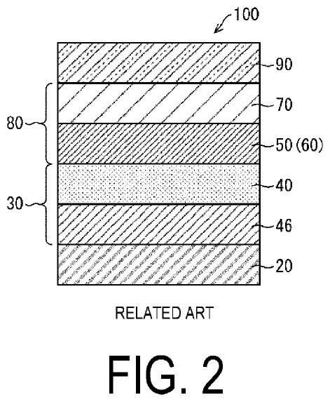

FIG. 2 is a diagram illustrating a cross-sectional configuration of a display device 100 according to a known example. The display device 100 illustrated in FIG. 2 differs in the configuration of the circular polarizer 80 compared to the display device 10 illustrated in FIG. 1. Specifically, in the display device 100, the phase difference layer 50 is formed by a molded film. Specifically, the phase difference layer 50 is a polycarbonate film, and the film is layered to the linear polarizing layer 70. Then, the value of the phase difference of this film is λ₀/4.

The display device 100 illustrated in FIG. 2 differs in the value of the phase difference of the touch panel base material 40 compared to the display device 10 illustrated in FIG. 1. In the display device 10, the value of the phase difference of the touch panel base material 40 is λ₀/4+α, while at the display device 100 is 0. This is because, in the display device 100, only the phase difference layer 50 has the value of the total phase difference 60 being λ₀/4.

The display device 100 illustrated in FIG. 2 has a large thickness and is unsuitable for current display devices required to be light, thin, short, and small. The main cause of the large thickness of the display device 100 is that the phase difference layer 50 is formed by a molded film. In contrast, in the display device 10 illustrated in FIG. 1, the phase difference layer 50 is formed by a coating film. As such, the thickness of the phase difference layer 50 can be reduced in the display device 10, and thus the overall thickness of the display device 10 can be reduced.

Specifically, the polycarbonate film used in the display device 100 has a thickness of 50 um, while the coating film of the display device 10 has a thickness of 5 um.

As such, the display device 10 is light, think, short, and small, and is suitable for required characteristics. Note that the thickness of the touch panel base material 40 is 20 to 30 um.

### Known Configuration 2

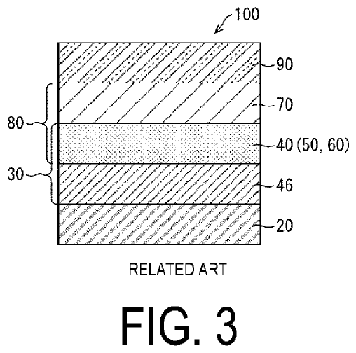

FIG. 3 is a diagram illustrating a cross-sectional configuration of a display device 100 according to another known example. The display device 100 illustrated in FIG. 3 differs in the configuration of the circular polarizer 80 and the touch panel 30 compared to the display device illustrated in FIG. 1. Specifically, in the display device 10 of FIG. 1, the phase difference layer 50 of the circular polarizer 80 and the touch panel base material 40 of the touch panel 30 are separate members, while in the display device 100 in FIG. 3, the phase difference layer 50 and the touch panel base material 40 are the same member. In other words, the touch panel base material 40 also has a phase difference of λ₀/4 and functions as the phase difference layer 50. The total phase difference 60 is the phase difference of the touch panel base material 40.

In this example, the touch panel base material 40 is formed by a high reliability resin film, in particular, a cycloolefin polymer film. Here, as described above, the cycloolefin polymer has a flat wavelength dispersion (because the wavelength dispersion is a material-specific characteristic, it is difficult to change the characteristic). Therefore, in the circular polarizer 80, the reflectivity varies depending on the wavelength, the reflected light is colored, and the display quality of the display device is reduced. Thus, the display device 100 illustrated in FIG. 3 is unsuitable as a display device. In contrast, because the display device 10 illustrated in FIG. 1 has the total phase difference 60 having a negative wavelength dispersion, the display device suppresses the coloration of the reflected light, and is suitable as a display device.

Here, in the display device 100 illustrated in FIG. 3, it is conceivable to form the touch panel base material 40 from a film having a negative wavelength dispersion, such as a polycarbonate film. However, such a film has poor heat resistance, and it is difficult to form a touch panel electrode such as ITO on the surface thereof. Therefore, it is not practical to form the touch panel base material 40 with a film having a negative wavelength dispersion.

### Viewing Angle Characteristics

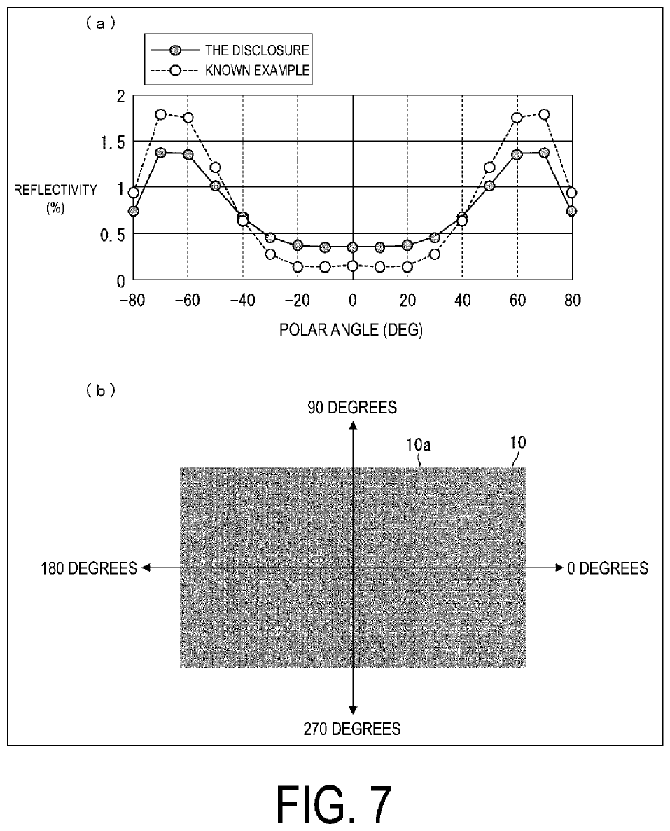

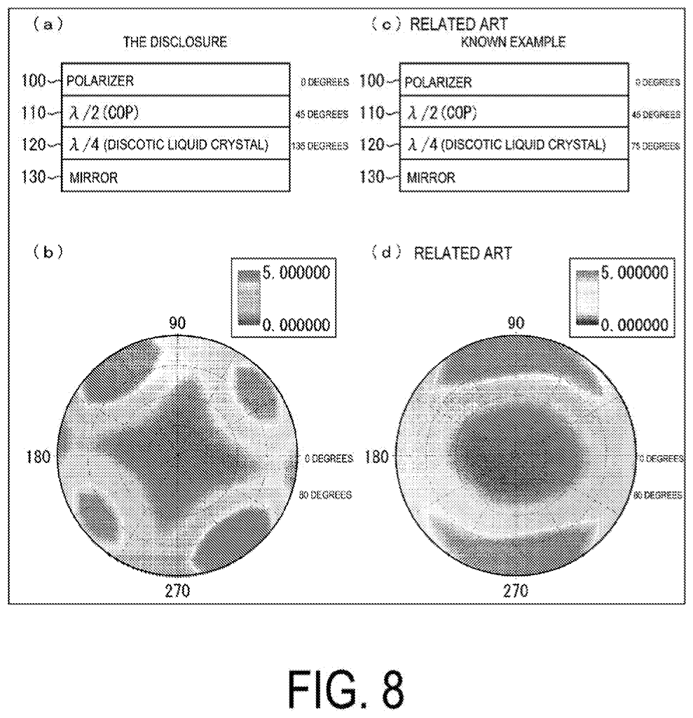

Next, viewing angle characteristics will be described with reference to FIG. 7 and FIG. 8. FIG. 7 is a diagram illustrating viewing angle characteristics of circular polarizers according to the disclosure and a known example. FIG. 8 is a diagram illustrating layer configurations of the circular polarizers illustrated in FIG. 7 with the viewing angle characteristics.

The circular polarizer of the disclosure indicated in solid line in FIG. 7(a) has better viewing angle characteristics than the circular polarizer of the known example indicated by the dotted line. Here, better viewing angle characteristics mean that an antireflective effect can be obtained to a wider angle (wide angle side). Hereinafter, this point will be described.

FIG. 7(b) is a diagram illustrating the direction of the angle. In a case that the rectangular display device 10 is placed in the landscape direction (in other words, 10 a is a frame on the upper side of the display device 10), the horizontal direction thereof is 0 degrees, and the counterclockwise direction is the positive direction.

As illustrated in FIGS. 8(a) and (c), the layer configurations of the circular polarizers in which the viewing angle characteristics are measured have a four-layer layered body of a mirror, a λ/4 phase difference layer, a λ/2 phase difference layer, and a polarizer in this order, and are common. Here, the λ/4 phase difference layer is composed of a discotic liquid crystal, the λ/2 phase difference layer is formed from a high reliability resin film, and the polarizer is a linear polarizer.

The difference between the disclosure illustrated in FIG. 8(a) and the known example illustrated in FIG. 8(c) is the angle formed by the slow axis between the λ/4 phase difference layer and the λ/2 phase difference layer. In the disclosure, the angle is 90 degrees, and in the known example, the angle is 60 degrees.

Note that the slow axis of λ/4 is arranged in the 135 degree direction in the disclosure and 75 degree direction in the known example. All of the polarizers have the optical axis disposed in the 0 degree direction.

As illustrated in FIG. 7(a), FIGS. 8(a), and (b), it can be seen that the circular polarizer of the disclosure has low dependence of reflectivity on polar angles, in particularly, in transverse directions (0 degrees-180 degrees directions), compared to the circular polarizer of the known example, resulting in good viewing angle characteristics for good reflection prevention.

Note that the above description has been given with the reference wavelength λ₀, but the same applies to other wavelengths.

### Supplement

A display device according to a first aspect of the disclosure is a display device including a light-emitting layer, a touch panel, a phase difference layer, and a linear polarizing layer, wherein the touch panel and the phase difference layer are provided between the light-emitting layer and the linear polarizing layer, the touch panel includes a touch panel base material and a touch panel electrode, the touch panel base material is formed from a resin film, a phase difference of the resin film is (λ₀/4)+α₀ at reference wavelength λ₀, the phase difference layer is formed from a polymerizable liquid crystal material, a phase difference α of the phase difference layer is α₀ at reference wavelength λ₀, and a slow axis of the resin film is orthogonal to a slow axis of the phase difference layer.

In a display device according to a second aspect of the disclosure, a wavelength dispersion of the phase difference of the resin film is a flat wavelength dispersion.

In a display device according to a third aspect of the disclosure, the α₀ is λ₀/4 at reference wavelength λ₀.

In a display device according to a fourth aspect of the disclosure, a total phase difference combining the phase difference of the resin film and the phase difference of the phase difference layer is a negative wavelength dispersion of ¼λ.

In a display device according to a fifth aspect of the disclosure, the phase difference of the phase difference layer is a positive wavelength dispersion.

In a display device according to a sixth aspect of the disclosure, the phase difference layer is a λ/4 plate formed from a positive wavelength dispersion material.

In a display device according to a seventh aspect of the disclosure, the display device includes a frame, and a direction of an optical axis of the linear polarizing layer is a direction parallel to any one side of sides of the frame.

In a display device according to an eighth aspect of the disclosure, the display device includes a frame, and a direction of an optical axis of the linear polarizing layer is a direction forming an angle of 45 degrees with any one of sides of the frame.

In a display device according to a ninth aspect of the disclosure, the phase difference layer is formed by application.

In a display device according to a 10th aspect of the disclosure, the linear polarizing layer is formed by application.

In a display device according to an 11th aspect of the disclosure, the touch panel electrode is formed from a transparent conductive film.

In a display device according to a 12th aspect of the disclosure, the resin film is formed from a cycloolefin polymer.

In a display device according to a 13th aspect of the disclosure, a circular polarizer is constituted with the touch panel, the phase difference layer, and the linear polarizing layer.

In a display device according to a 14th aspect of the disclosure, a liquid crystal material having a negative double refraction is used for the phase difference layer.

In a display device according to a 15th aspect of the disclosure, a wavelength dispersion of the phase difference of the resin film is a flat wavelength dispersion, the phase difference layer is a λ/4 plate formed from a positive wavelength dispersion material, and a total phase difference combining the phase difference of the resin film and the phase difference of the phase difference layer is a negative wavelength dispersion of ¼λ.

A method of manufacturing a display device according to a 16th aspect of the disclosure is a method of manufacturing a display device including a light-emitting layer, a touch panel, a phase difference layer, and a linear polarizing layer, the method including the steps of: preparing a resin film having a phase difference of (λ₀/4)+α at reference wavelength λ₀ as a touch panel base material; forming a touch panel electrode on one surface side of the resin film to form the touch panel; applying, aligning, and curing a polymerizable liquid crystal material on other surface side of the resin film to form the phase difference layer; providing one of the light-emitting layer and the linear polarizing layer on the phase difference layer; and layering other of the light-emitting layer and the linear polarizing layer on a surface side of the touch panel base material on which the touch panel electrode is formed.

### Additional Items

The disclosure is not limited to the embodiments described above. Embodiments obtained by appropriately combining technical approaches disclosed in the corresponding embodiments are also included within the technical scope of the disclosure. Moreover, novel technical features can be formed by combining the technical approaches disclosed in the embodiments.

The display according to the present embodiments is not particularly limited as long as it is a display panel including a display element. The display element is a display element of which luminance and transmittance are controlled by an electric current, and examples of the electric current-controlled display element include an organic Electro Luminescence (EL) display provided with an Organic Light Emitting Diode (OLED), an EL display such as an inorganic EL display provided with an inorganic light emitting diode, and a QLED display provided with a Quantum dot Light Emitting Diode (QLED).

1. A display device comprising:
a light-emitting layer;
a touch panel;
a phase difference layer; and
a linear polarizing layer,
wherein the touch panel and the phase difference layer are provided between the light-emitting layer and the linear polarizing layer,
the touch panel includes a touch panel base material and a touch panel electrode,
the touch panel base material is formed from a resin film,
a phase difference of the resin film is (λ₀/4)+α₀ at reference wavelength λ₀,
the phase difference layer is formed from a polymerizable liquid crystal material,
a phase difference α of the phase difference layer is α₀ at reference wavelength λ₀, and
a slow axis of the resin film is orthogonal to a slow axis of the phase difference layer.

2. The display device according to claim 1,
wherein a wavelength dispersion of the phase difference of the resin film is a flat wavelength dispersion.

3. The display device according to claim 1,
wherein the α₀ is λ₀/4 at reference wavelength λ₀.

4. The display device according to claim 1,
wherein a total phase difference combining the phase difference of the resin film and the phase difference of the phase difference layer is a negative wavelength dispersion of ¼λ.

5. The display device according to claim 1,
wherein the phase difference of the phase difference layer is a positive wavelength dispersion.

6. The display device according to claim 5,
wherein the phase difference layer is a λ/4 plate formed from a positive wavelength dispersion material.

7. The display device according to claim 1,
the display device comprising a frame,
wherein a direction of an optical axis of the linear polarizing layer is a direction parallel to any one side of sides of the frame.

8. The display device according to claim 1,
the display device comprising a frame,
wherein a direction of an optical axis of the linear polarizing layer is a direction forming an angle of 45 degrees with any one of sides of the frame.

9. The display device according to claim 1,
wherein the phase difference layer is formed by application.

10. The display device according to claim 1,
wherein the linear polarizing layer is formed by application.

11. The display device according to claim 1,
wherein the touch panel electrode is formed from a transparent conductive film.

12. The display device according to claim 1,
wherein the resin film is formed from a cycloolefin polymer.

13. The display device according to claim 1,
wherein a circular polarizer is constituted with the touch panel, the phase difference layer, and the linear polarizing layer.

14. The display device according to claim 1,
wherein a liquid crystal material having a negative double refraction is used for the phase difference layer.

15. The display device according to claim 1,
wherein a wavelength dispersion of the phase difference of the resin film is a flat wavelength dispersion,
the phase difference layer is a λ/4 plate formed from a positive wavelength dispersion material, and
a total phase difference combining the phase difference of the resin film and the phase difference of the phase difference layer is a negative wavelength dispersion of ¼λ.

16. A method of manufacturing a display device including a light-emitting layer, a touch panel, a phase difference layer, and a linear polarizing layer, the method comprising the steps of:
preparing a resin film having a phase difference of (λ₀/4)+α at reference wavelength λ₀ as a touch panel base material;
forming a touch panel electrode on one surface side of the resin film to form the touch panel;
applying, aligning, and curing a polymerizable liquid crystal material on other surface side of the resin film to form the phase difference layer;
providing one of the light-emitting layer and the linear polarizing layer on the phase difference layer; and
layering other of the light-emitting layer and the linear polarizing layer on a surface side of the touch panel base material on which the touch panel electrode is formed.
